(19) United States
(12) Patent Application Publication
(10) Pub. No.: US 2008/0297185 A1
(43) Pub. Date: Dec. 4, 2008

(54) Multi probe card unit, probe test device including the multi probe card unit, and methods of fabricating and using the same

(75) Inventors: Sang-gu Kang, Seoul (KR); Chang-Hyun Cho, Suwon-si (KR); Sung-mo Kang, Suwon-si (KR); Sang-kyo Yoo, Suwon-si (KR); Joon-yeon Kim, Seongnam-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/155,185

(22) Filed: May 30, 2008

(30) Foreign Application Priority Data
May 31, 2007 (KR) 10-2007-0053483

(51) Int. Cl. G01R 1/073; H01R 43/00

(52) U.S. Cl. 324/754; 29/884

(57) ABSTRACT

A multi probe card unit, a probe test device including the multi probe card unit, and methods of fabricating and using the same are provided. The multi probe card unit may include at least one probe card including a first plurality of probes on a first surface of the at least one probe card and a second plurality of probes on a second surface of the at least one probe card.

### PRIORITY STATEMENT

This application claims priority under 35 U.S.C. §119 to Korean Patent Application No. 10-2007-0053483, filed on May 31, 2007, in the Korean Intellectual Property Office (KIPO), the entire contents of which are herein incorporated by reference.

### BACKGROUND

1. Field

Example embodiments relate to a multi probe card unit, a probe test device which includes the multi probe card unit, and methods of fabricating the same. Other example embodiments relate to a semiconductor test device, and more particularly, to a probe card that is used in an electrical die sorting (EDS) process for determining whether chips formed on a wafer are acceptable for their intended purpose.

2. Description of the Related Art

A process of manufacturing a semiconductor device may include fabrication, electrical die sorting (EDS) and assembly processes. The fabrication process is a process in which a predetermined or given pattern may be formed on a wafer to constitute a plurality of integrated circuits, and the assembly process may be a process in which the wafer, on which the integrated circuits are formed, is cut into chip units to be packaged.

The EDS process may be a process in which the electric properties of the wafer are tested prior to cutting the wafer into chip units. By performing the EDS process to repair or remove undesirable chips, assembly process and package test costs may be reduced.

During the performing of the EDS process, a wafer to be tested may be loaded on a probe test device to be aligned, and the probe card may be moved to contact the wafer. Thus, chips may be tested to determine whether they operate normally or are defective. The probe card may be formed by protruding probes from a printed circuit board, wherein the size of each of the probes may be relatively fine to correspond to an arrangement width of pads formed on the chips. The wafer may be tested by contact between each of the probes and the pads. A test signal from the probe test device may be transferred to a circuit included in a device through the probes contacting the pads of the chips. Accordingly, the probes may be arranged to correspond to the pads formed on the wafer. The probes of the probe card may be aligned to the pads using an aligning method of the probe test device.

### SUMMARY

Example embodiments provide a multi probe card unit and a probe test device, including the multi probe card unit, that may simultaneously test a plurality of wafers to increase the test capacity of an electrical die sorting (EDS) process. Example embodiments also provide for methods of fabricating the multi probe card unit and probe test device.

However, example embodiments are not restricted to the ones set forth herein. The above and other features and advantages of example embodiments will become more apparent to one of ordinary skill in the art to which example embodiments pertain by referencing a detailed description of example embodiments given below.

According to example embodiments, a multi probe card unit may include at least one probe card including a first plurality of probes on a first surface of the at least one probe card and a second plurality of probes on a second surface of the at least one probe card.

According to example embodiments, a probe test device may include a multi probe card unit wherein the multi probe card unit includes at least one probe card which may include a first plurality of probes on a first surface of the at least one probe card and a second plurality of probes on a second surface of the at least one probe card, a frame to support the multi probe card unit, and a plurality of chucks for transferring a plurality of wafers to the multi probe card unit for testing.

According to example embodiments, a method of manufacturing a multi probe card unit may include forming or providing at least one probe card, forming a first plurality of probes on a first surface of the at least one probe card, and forming a second plurality of probes on a second surface of the at least one probe card.

According to example embodiments, a method of fabricating a probe test device may include forming at least one multi probe card unit wherein the multi probe card unit is formed by forming at least one probe card, forming a first plurality of probes on a first surface of the at least one probe card, forming a second plurality of probes on a second surface of the at least one probe card, placing the multi probe card unit in contact with a frame to structurally support the multi probe card unit and supplying a plurality of chucks to transfer a plurality of wafers to the multi probe card unit for testing.

According to example embodiments, a method of using a probe test device may include mounting at least a first wafer on at least a first chuck and mounting at least a second wafer on at least a second chuck wherein the first and second wafer include at least one contact pad, moving the first and second chucks with the first and second wafers towards a multi probe card unit wherein the multi probe card unit includes at least one probe card including a first plurality of probes on a first surface of the at least one probe card and a second plurality of probes on a second surface of the at least one probe card so that the first and second plurality of probes on the first and second surface of the at least one probe card contact the at least one contact pad of the first wafer and the at least one contact pad of the second wafer, and simultaneously testing the first and second wafers by contact between the pads of the wafers and the probes.

### BRIEF DESCRIPTION OF THE DRAWINGS

Example embodiments will be more clearly understood from the following detailed description taken in conjunction with the accompanying drawings. FIGS. 1-4 represent non-limiting, example embodiments as described herein.

FIG. 1 is a side view of a multi probe card unit including a probe card having probes formed on at least two surfaces of the probe card and a probe test device including the multi probe card unit according to example embodiments;

FIG. 2 is a side view of a multi probe card unit including a plurality of probe cards disposed opposite to each other and a probe test device including the multi probe card unit according to example embodiments;

FIG. 3 is a side view of a multi probe card unit including a plurality of probe cards disposed in the same direction and a probe test device including the multi probe card unit according to example embodiments; and

FIG. 4 is a side view of a multi probe card unit including probe card vertically disposed and a probe test device including the multi probe card unit according to example embodiments.

### DETAILED DESCRIPTION OF EXAMPLE EMBODIMENTS

Example embodiments are described more fully hereinafter with reference to the accompanying drawings. Example embodiments may, however, be embodied in many different forms and should not be construed as limited to the embodiments set forth herein. Rather, these embodiments are provided so that this disclosure will be thorough and complete, and will fully convey the scope of example embodiments to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements of features. Thus, the exemplary term “below” can encompass both an orientation of above and below. The device may be otherwise oriented (rotated 90 degrees or at other orientations) and the spatially relative descriptors used herein interpreted accordingly.

Embodiments described herein will refer to plan views and/or cross-sectional views by way of ideal schematic views. Accordingly, the views may be modified depending on manufacturing technologies and/or tolerances. Therefore, example embodiments are not limited to those shown in the views, but include modifications in configuration formed on the basis of manufacturing processes. Therefore, regions exemplified in figures have schematic properties and shapes of regions shown in figures exemplify specific shapes of regions of elements and do not limit example embodiments.

If probes are formed on only one surface of a probe card, only one sheet of a wafer may be tested during one movement. Example embodiments provide a multi probe card unit and a probe test device, which may include the same, that may test a plurality of wafers and thus may overcome the conventional problem of the limited test capacity of a single probe card. The multi probe card unit, according to example embodiments, may simultaneously test at least one wafer unlike the conventional art. The probe test device, which may include the multi probe card unit, may increase the number of wafers to be simultaneously tested without restriction (e.g. four wafers or six wafers).

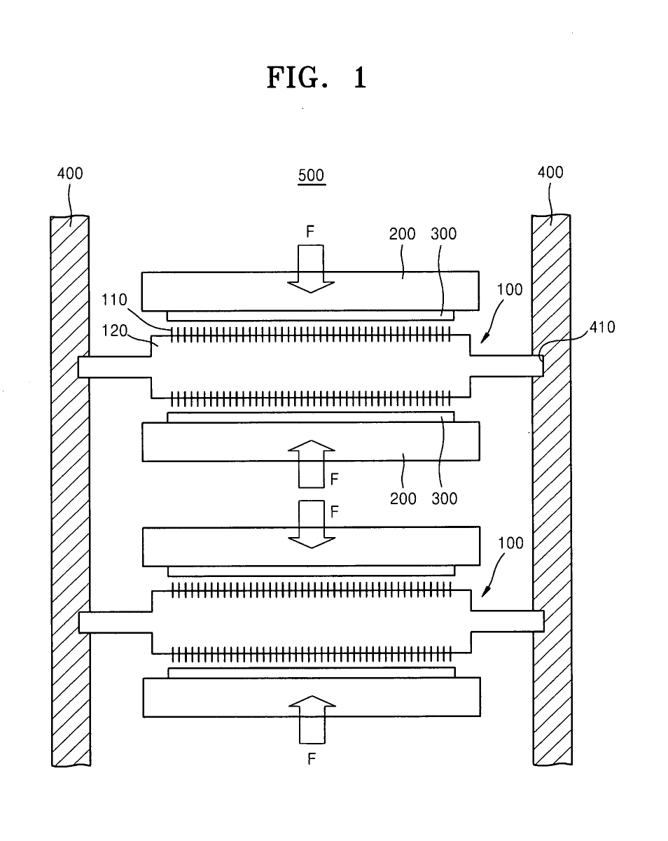

FIGS. 1-4 are views of multi probe card units 100 and probe test devices 500 including the multi probe card units 100 that are classified according to the alignment or position of probe cards and the alignment of probes, according to example embodiments. Although only two multi probe card units 100 are included in a frame 400 as illustrated in FIGS. 1-4, the number of multi probe card units 100 included in the probe test device 500 is not limited. Referring to FIGS. 1 through 4, the probe test device 500 may include a multi probe card unit 100, a frame 400 including a slot 410 into which the multi probe card unit 100 is inserted, and a chuck 200 transferring a wafer 300. At least one multi probe card unit 100 may be mounted into the slot 410 formed in the frame 400 of the probe test device 500. The multi probe card unit 100 may be inserted into the slot 410 which may be fixed at a predetermined or given location. Probes 110 of the multi probe card unit 100 contact pads (not shown) on the wafer 300 by movement of the wafer 300 positioned on the chuck 200. Although not illustrated, a wafer may be fixed at a predetermined or given location, the multi probe card unit 100 may be moved, and the probes 110 may contact pads on the wafer 300.

FIG. 1 is a side view of a multi probe card unit 100 including a probe card 120 having probes 110 formed on at least two surfaces of the probe card 120 and a probe test device 500 including the multi probe card unit 100, according to example embodiments. Referring to FIG. 1, the wafer 300 may be loaded in a wafer transfer robot (not shown) which may be transferred to the probe test device 500 for an electrical die sorting (EDS) test process. The wafer 300 may be carried out of the probe transfer robot to be put in the probe test device 500, and then the wafer 300 may be loaded in the chuck 200 to ascend and descend to a predetermined or given location.

According to non-limiting example embodiments illustrated in FIG. 1, the probes 110 may be formed on at least two surfaces of the probe card 120. When the wafer 300 loaded on the chuck 200, which is to be transferred, approaches the probe card 120, pads formed on the wafer 300 may contact the probes 110 of the multi probe card unit 100 and may perform a transmission test.

The probes 110 may be formed on an upper surface of the probe card 120. The probes 110 may contact some of the pads of the wafer 300, which may approach the upper surface of the probe card 120, by a predetermined or given contact force F. The probes 110 may be formed on a lower surface of the probe card 120. The probes 110 may contact pads of another wafer 300, which approaches the lower surface of the probe card 120, by a predetermined or given contact force F.

A wafer test signal that may be provided by the probe test device 500 may be transferred to the probe card 120, and may be transferred to the pads of the wafer 300 through the probes 110. An inner circuit, which may constitute a chip, may track the wafer test signal, and then, the chips may be checked to determine whether they function normally. Although not illustrated, a signal transfer device may be further provided, and thus an electric signal for a wafer-test may be transferred from a probed test device to a probe card and a probe.

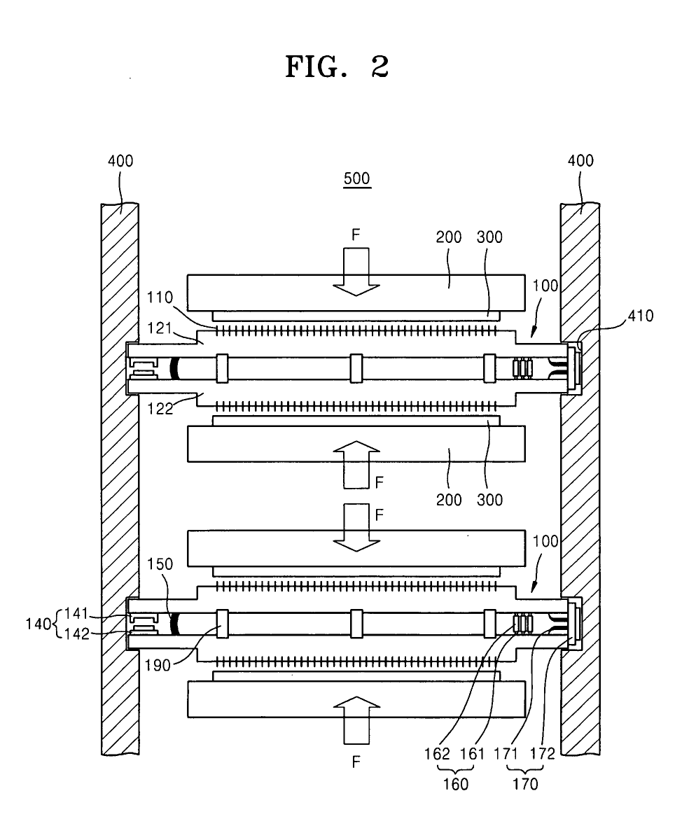

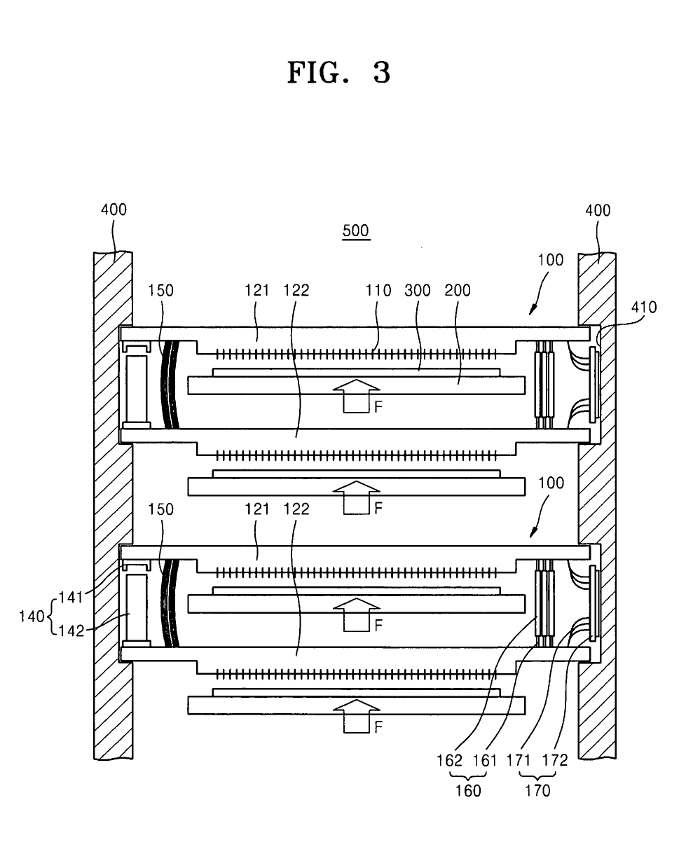

FIG. 2 is a side view of a multi probe card unit 100 including a plurality of probe cards 121 and 122 disposed opposite to each other and a probe test device 500 including the multi probe card unit 100, according to example embodiments. FIG. 3 is a side view of a multi probe card unit 100 including a plurality of probe cards 121 and 122 disposed in the same direction and a probe test device 500 including the multi probe card unit 100, according to example embodiments. Unlike FIG. 1, the multi probe card units 100 and the probe test devices 500 illustrated in FIGS. 2 and 3 contain a connection unit that may electrically connect a plurality of probe cards (121 and 122) including probes 110.

Referring to FIGS. 2 and 3, the multi probe card unit 100 may include a first probe card 121 and a second probe card 122, e.g., at least two probe cards. As illustrated in FIG. 2, the first probe card 121 and the second probe card 122 may be arranged so that the probes 110 on the first probe card 121 may protrude in a direction opposite to that of the probes 110 on the second probe card 122. Alternatively, as illustrated in FIG. 3, the first probe card 121 and the second probe card 122 may be arranged so that the probes 110 on the first probe card 121 may protrude in the same direction as that of the probes 110 on the second probe card 122. In FIG. 2, the multi probe card unit 100 may be disposed between a plurality of wafers 300, such that the wafers 300 may approach the multi probe card unit 100 from opposite directions, e.g., from above the first probe card 121 and from below the second probe card 122. In FIG. 3, the wafers 300 may approach the first probe card 121 and the second probe card 122 in the same direction.

For example, when an upper direction of the probe test device 500 is denoted by a first direction, and a lower direction of the probe test device 500 is denoted by a second direction, the first and second directions may be opposite to each other. Referring to FIG. 2, the probes 110 of the first probe card 121 may protrude in the first direction. The wafer 300 above the first probe card 121 may approach the first probe card 121 in the second direction. The probes 110 of the second probe card 122 may protrude in the second direction. The wafer 300 below the second probe card 122 may approach the second probe card 122 in the first direction.

The first direction and the second direction may denote different directions from the above directions. For example, in FIG. 3, when the lower direction of the probe test device 500 is denoted by the first direction, and the upper direction of the probe test device 500 is denoted by the second direction, the probes 110 of the first probe card 121 and the second probe card 122 may protrude in the same direction, and each wafer 300 moved in the second direction may approach the first probe card 121 and the second probe card 122.

The wafers 300, which may be positioned on the chucks 200 to be transferred, may contact the first probe card 121 and the second probe card 122 by a predetermined or given contact force F. In the multi probe card unit 100 illustrated in FIG. 2, because the contact force F may be applied in different directions from each other, the first probe card 121 and the second probe card 122 may be moved or broken due to the contact force F. To prevent or reduce this, a contact force adjustment unit 190 may be provided. The contact force adjustment unit 190 may be disposed between the first probe card 121 and the second probe card 122, and may be formed of an elastic material or a visco-elastic material. Alternatively, the contact force adjustment unit 190 may be a pneumatic cylinder, a hydraulic cylinder, or a solenoid in order to actively adjust the contact force F.

A connection unit electrically connecting the first probe card 121 to the second probe card 122 may be at least one of a ZIF connector 140, a coaxial cable 150, a pogo pin 160 and an edge connector 170. In FIGS. 2 and 3, each of the ZIF connector 140, the coaxial cable 150, the pogo pin 160 and the edge connector 170 are illustrated as electrically connecting the first probe card 121 to the second probe card 122. However, only one of the ZIF connector 140, the coaxial cable 150, the pogo pin 160 and the edge connector 170 may be provided or a connector having a different type may be provided.

In a semiconductor test device, probe cards may be connected to provide reliability. In a conventional connection method in which an increased contact force may be applied to a connection portion between metals, metal plating formed on a contact point may be damaged or the lifetime of a device may be reduced. To solve these problems, the ZIF connector 140 may be provided so that a contact force between two connectors 141 and 142 may be substantially zero. The coaxial cable 150 may be effective for removing electric noise that may be induced through the coaxial cable 150. The pogo pin 160 may include a body 162 filled with air, a fluid or an elastic material, and a contact pin 161 moving inside the body 162 to connect the contact points to each other. The pogo pin 160 may connect two contact points by an elastic force or a visco-elastic force, and may maintain a predetermined or given contact force, although the contact pin 161 is worn. In addition, the pogo pin 160 may have an increased lifespan, and may reduce abrasion between metals that may be connected in a conventional connector. The edge connector 170 may be disposed on an edge of the probe card 121 and 122, and may be used to connect two probe cards 120 irrespective of an interval between the two probe cards 120. The edge connector 170 may include a connection line 171 connected to the first and second probe cards 121 and 122, and a connection unit 172 connected to the connection line 171.

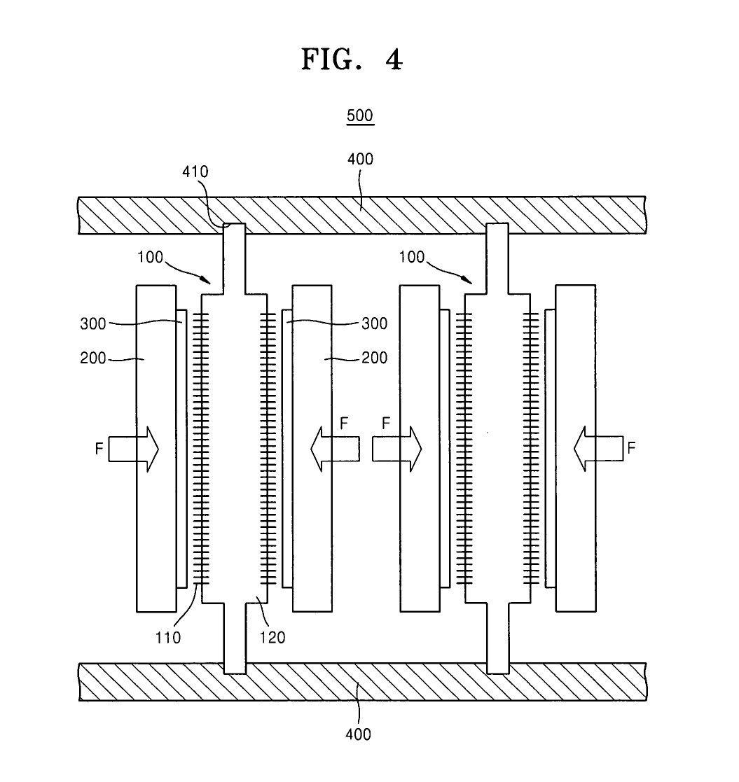

FIG. 4 is a side view of a multi probe card unit 100 including a vertically disposed probe card 120 and a probe test device 500 including the multi probe card unit 100, according to example embodiments. In the multi probe card units 100 of FIGS. 1-3, the multi probe card unit 100 and the probe card 120 may be disposed in a horizontal direction and the chuck 200 is moved in a vertical direction. However, example embodiment are not limited thereto, and in the multi probe card units 100 of FIGS. 1-3, the multi probe card unit 100 and the probe card 120 may be disposed in a vertical direction and the chuck 200 may be moved in a horizontal direction in the multi probe card unit 100 of FIG. 4. Although not illustrated, in the probe test device 500 which may include the multi probe card unit 100 or the probe card 120 illustrated in FIG. 2 or 3, the multi probe card unit 100 or the probe card 120 may extend in a vertical direction.

As described above, in a multi probe card unit according to example embodiments and a probe test device including the multi probe card unit, the limited test capacity of a conventional electrical die sorting (EDS) process may be overcome, and a plurality of wafers may be simultaneously tested. Accordingly, the space required for probe cards may be reduced and the test capacity of an EDS process may be increased.

While example embodiments have been particularly shown and described with reference to example embodiments thereof, it will be understood by those of ordinary skill in the art that various changes in form and details may be made therein without departing from the spirit and scope of the following claims.

What is claimed is:

1. A multi probe card unit comprising:
at least one probe card including a first plurality of probes on a first surface of the at least one probe card and a second plurality of probes on a second surface of the at least one probe card.

2. The multi probe card unit of claim 1, wherein the first plurality of probes and the second plurality of probes are on different surfaces of the same probe card.

3. The multi probe card unit of claim 1, wherein:
the at least one probe card is a first probe card and a second probe card, and the first surface is on the first probe card and the second surface is on the second probe card such that the first plurality of contacts are on the first probe card and the second plurality of contacts are on the second probe card.

4. The multi probe card unit of claim 3, wherein the first probe card and the second probe card are arranged so that the first plurality of probes on the first probe card protrude in an opposite direction to that of the second plurality of probes on the second probe card.

5. The multi probe card unit of claim 4, further comprising:
a contact force adjustment unit between the first probe card and the second probe card so as to adjust a contact force of the wafer applied between the first probe card and the second probe card.

6. The multi probe card unit of claim 5, wherein the contact force adjustment unit comprises an elastic body.

7. The multi probe card unit of claim 3, wherein the first probe card and the second probe card are arranged so that the first plurality of probes on the first probe card protrudes in the same direction as that of the second plurality of probes on the second probe card.

8. The multi probe card unit of claim 3, further comprising a connection unit to electrically connect the first probe card with the second probe card.

9. The multi probe card unit of claim 8, wherein the connection unit includes at least one of a ZIF connector, a coaxial cable, a pogo pin and an edge connector.

10. The multi probe card unit of claim 1, wherein the at least one probe card is in a vertical direction or a horizontal direction.

11. A probe test device comprising:
the multi probe card unit of claim 1;
a frame to support the multi probe card unit; and
a plurality of chucks for transferring a plurality of wafers to the multi probe card unit for testing.

12. The probe test device of claim 11, wherein the first plurality of probes and the second plurality of probes are on different surfaces of the same probe card.

13. The probe test device of claim 11, wherein:
the at least one probe card is a first probe card and a second probe card, and the first surface is on the first probe card and the second surface is on the second probe card such that the first plurality of contacts are on the first probe card and the second plurality of contacts are on the second probe card; and
a connection unit to electrically connect the first probe card with the second probe card.

14. The probe test device of claim 13, wherein the first probe card and the second probe card are arranged so that the first plurality of probes on the first probe card protrude in an opposite direction to that of the second plurality of probes on the second probe card.

15. The probe test device of claim 14, further comprising:
a contact force adjustment unit between the first probe card and the second probe card so as to adjust a contact force of the wafer applied between the first probe card and the second probe card.

16. The probe test device of claim 13, wherein the first probe card and the second probe card are arranged so that the first plurality of probes on the first probe card protrudes in the same direction as that of the second plurality of probes on the second probe card.

17. The probe test device of claim 13, wherein the connection unit includes at least one of a ZIF connector, a coaxial cable, a pogo pin and an edge connector.

18. The probe test device of claim 11, wherein the frame is slotted, and the slots are configured to receive the multi probe test card unit.

19. A method of fabricating a multi probe card unit comprising:
providing at least one probe card;
forming a first plurality of probes on a first surface of the at least one probe card; and
forming a second plurality of probes on a second surface of the at least one probe card.

20. A method of fabricating a probe test device, comprising:
forming at least one multi probe card unit by the method of claim 19;
placing the at least one multi probe card unit in contact with a frame configured to structurally support the at least one multi probe card unit; and
supplying a plurality of chucks to transfer a plurality of wafers to the at least one multi probe card unit for testing.

21. A method of using a probe test device, comprising:
mounting at least a first wafer on at least a first chuck and mounting at least a second wafer on at least a second chuck wherein the first and second wafer include at least one contact pad;
moving the first and second chucks with the first and second wafers towards a multi probe card unit, wherein the multi probe card unit includes at least one probe card including a first plurality of probes on a first surface of the at least one probe card and a second plurality of probes on a second surface of the at least one probe card so that the first and second plurality of probes on the first and second surface of the at least one probe card contact the at least one contact pad of the first wafer and the at least one contact pad of the second wafer; and
simultaneously testing the first and second wafers by contact between the pads of the wafers and the probes.

22. The method of claim 21, wherein the first wafer approaches the multi probe card unit in an opposite direction to the direction in which the second wafer approaches the multi probe card unit.

23. The method of claim 21, wherein the first wafer approaches the multi probe card unit in the same direction in which the second wafer approaches the multi probe card unit.
